(19) United States
(12) Patent Application Publication
(10) Pub. No.: US 2026/0257477 A1
(43) Pub. Date: Sep. 3, 2026

(54) INKJET PRINTING APPARATUS, INKJET PRINTING METHOD, AND ELECTRONIC DEVICE

(71) Applicant: Samsung Display Co., Ltd., Yongin-si (KR)

(72) Inventors: JAESIK KIM, Yongin-si (KR); JUNGHAN SEO, Yongin-si (KR); WOO YONG SUNG, Yongin-si (KR); SEUNGYONG SONG, Yongin-si (KR); SEUNGHO YOON, Yongin-si (KR); BYEONGJUN LEE, Yongin-si (KR)

(21) Appl. No.: 19/339,078

(22) Filed: Sep. 24, 2025

(30) Foreign Application Priority Data
Feb. 28, 2025 (KR) 10-2025-0026370

(51) Int. Cl. B41J 2/14; B41J 2/16; B41J 3/407

(52) U.S. Cl. CPC B41J 2/1433; B41J 2/14201; B41J 2/162; B41J 2/1642; B41J 2/1646; B41J 3/407; B41J 2202/03

(57) ABSTRACT

An inkjet printing apparatus includes: a substrate on a stage; and an inkjet head on the stage and having a head part including: a nozzle plate having a nozzle part configured to eject an ink and a lower surface facing the stage and having a first area, a second area, and a third area; an organic layer on the lower surface of the nozzle plate in the second area and the third area; an inorganic layer on a lower surface of the organic layer in the third area; a first oxide layer on the lower surface of the nozzle plate in the first to third areas and covering the nozzle plate, the organic layer, and the inorganic layer; a second oxide layer on a lower surface of the first oxide layer in the first to third areas; and a liquid-repellent layer on a lower surface of the second oxide layer.

### CROSS-REFERENCE TO RELATED APPLICATION

The present application claims priority to and the benefit of Korean Patent Application No. 10-2025-0026370, filed on Feb. 28, 2025, in the Korean Intellectual Property Office, the entire disclosure of which is incorporated herein by reference.

### BACKGROUND

### 1. Field

Aspects of some embodiments of the present disclosure relate to an inkjet printing apparatus and an inkjet printing method.

### 2. Description of the Related Art

With the development of information technology, the importance of a display device, which is a connection medium between a user and information, has been highlighted. For example, the use of display devices such as liquid crystal display (LCD) device, organic light emitting diode (OLED) display device, plasma display panel (PDP) device, quantum dot display device or the like is increasing.

In manufacturing the display device, inkjet printing technology is utilized. For example, an inkjet printing apparatus may form an alignment film or apply UV ink on a substrate in a process for manufacturing a liquid crystal display device. For example, the inkjet printing apparatus may apply an ink including an organic light-emitting material on a substrate in a process for manufacturing an organic light-emitting display device. For example, the inkjet printing apparatus may apply an ink including a quantum dot ink composition on a substrate in a process for manufacturing a quantum dot display device.

The above information disclosed in this Background section is only for enhancement of understanding of the background and therefore the information discussed in this Background section does not necessarily constitute prior art.

### SUMMARY

Aspects of some embodiments of the present disclosure relate to an inkjet printing apparatus and an inkjet printing method. For example, aspects of some embodiments of the present disclosure relate to an inkjet printing apparatus, an inkjet printing method, and an electronic device including a substrate on which ink ejected by the inkjet printing apparatus is applied.

Aspects of some embodiments of the present disclosure include an inkjet printing apparatus with relatively improved durability.

Aspects of some embodiments of the present disclosure include an inkjet printing method including a process for relatively improving durability.

Aspects of some embodiments of the present disclosure include an electronic device including a substrate on which ink ejected by the inkjet printing apparatus is applied.

An inkjet printing apparatus according to some embodiments of the present disclosure includes: a stage on which a substrate is loaded; and an inkjet head on the stage and including a head part. According to some embodiments, the head part includes: a nozzle plate having an inner side surface defining a nozzle part which ejects an ink and a lower surface facing the stage, the nozzle plate including a first area, a second area, and a third area sequentially arranged in a direction away from the nozzle part with respect to the nozzle part; an organic layer on the lower surface of the nozzle plate in the second area and the third area, and spaced apart from the first area in a plan view; an inorganic layer on a lower surface of the organic layer in the third area and spaced apart from the first area and the second area in the plan view; a first oxide layer on the lower surface of the nozzle plate in the first to third areas and covering the nozzle plate, the organic layer, and the inorganic layer; a second oxide layer on a lower surface of the first oxide layer in the first to third areas; and a liquid-repellent layer on a lower surface of the second oxide layer in the first to third areas.

According to some embodiments, the nozzle plate may further include a fourth area between the first area and the second area, and a fifth area between the second area and the third area.

According to some embodiments, the organic layer may be further on the lower surface of the nozzle plate in the fourth area and the fifth area. According to some embodiments, the organic layer may have a first inclined surface which is inclined with respect to the lower surface of the nozzle plate in the fourth area.

According to some embodiments, the inorganic layer may be further on the lower surface of the organic layer in the fifth area. According to some embodiments, the inorganic layer may have a second inclined surface which is inclined with respect to the lower surface of the nozzle plate in the fifth area.

According to some embodiments, the inorganic layer may be spaced apart from the fourth area in the plan view.

According to some embodiments, each of the first oxide layer and the second oxide layer may be further on the lower surface of the nozzle plate in the fourth area and the fifth area. According to some embodiments, each of the first oxide layer and the second oxide layer may cover the first inclined surface and the second inclined surface.

According to some embodiments, the first oxide layer may be arranged along profiles of the lower surface of the organic layer, the first inclined surface, a lower surface of the inorganic layer, and the second inclined surface. According to some embodiments, the second oxide layer may be arranged along a profile of the lower surface of the first oxide layer.

According to some embodiments, the liquid-repellent layer may be arranged along a profile of the lower surface of the second oxide layer.

According to some embodiments, the first oxide layer may entirely cover the inner side surface of the nozzle plate.

According to some embodiments, the inorganic layer may include silicon oxycarbide.

According to some embodiments, the first oxide layer may include aluminum oxide.

According to some embodiments, the second oxide layer may include silicon oxide.

An inkjet printing method according to some embodiments of the present disclosure includes: providing an initial inkjet head including a nozzle plate which has an inner side surface defining a nozzle part which ejects an ink and includes a first area, a second area, and a third area sequentially arranged in a direction away from the nozzle part with respect to the nozzle part, an organic layer on a lower surface of the nozzle plate in the second area and the third area, and spaced apart from the first area in a plan view, an inorganic layer on a lower surface of the organic layer in the third area and spaced apart from the first area and the second area in the plan view, and an initial liquid-repellent on a lower surface of the inorganic layer; removing the initial liquid-repellent layer; forming a first oxide layer covering the nozzle plate, the organic layer, and the inorganic layer on the lower surface of the nozzle plate in the first to third areas; forming a second oxide layer on a lower surface of the first oxide layer in the first to third areas; forming a liquid-repellent layer on a lower surface of the second oxide layer in the first to third areas, thereby forming an inkjet head including the nozzle plate, the organic layer, the inorganic layer, the first oxide layer, the second oxide layer, and the liquid-repellent layer; and ejecting the ink onto a substrate using the inkjet head.

According to some embodiments, the nozzle plate may further include a fourth area between the first area and the second area, and a fifth area between the second area and the third area.

According to some embodiments, the organic layer may be further on the lower surface of the nozzle plate in the fourth area and the fifth area, and may have a first inclined surface which is inclined with respect to the lower surface of the nozzle plate in the fourth area. According to some embodiments, the inorganic layer may be further on the lower surface of the organic layer in the fifth area, and may have a second inclined surface which is inclined with respect to the lower surface of the nozzle plate in the fifth area.

According to some embodiments, each of the first oxide layer and the second oxide layer may be further formed on the lower surface of the nozzle plate in the fourth area and the fifth area. According to some embodiments, each of the first oxide layer and the second oxide layer may cover the first inclined surface and the second inclined surface.

According to some embodiments, the first oxide layer may be formed along profiles of the lower surface of the organic layer, the first inclined surface, the lower surface of the inorganic layer, and the second inclined surface. According to some embodiments, the second oxide layer may be formed along a profile of the lower surface of the first oxide layer.

According to some embodiments, the liquid-repellent layer may be formed along a profile of the lower surface of the second oxide layer.

According to some embodiments, the first oxide layer may entirely cover the inner side surface of the nozzle plate.

An electronic device according to some embodiments of the present disclosure includes: a display device including a substrate on which an ink ejected by an inkjet printing apparatus is applied; and a processor which transmits an image data signal and an input control signal to the display device. According to some embodiments, the inkjet printing apparatus includes: a stage on which the substrate is loaded; a nozzle plate having an inner side surface defining a nozzle part which ejects the ink and a lower surface facing the stage, the nozzle plate including a first area, a second area, and a third area sequentially arranged in a direction away from the nozzle part with respect to the nozzle part; an organic layer on the lower surface of the nozzle plate in the second area and the third area, and spaced apart from the first area in a plan view; an inorganic layer on a lower surface of the organic layer in the third area and spaced apart from the first area and the second area in the plan view; a first oxide layer on the lower surface of the nozzle plate in the first to third areas and covering the nozzle plate, the organic layer, and the inorganic layer; a second oxide layer on a lower surface of the first oxide layer in the first to third areas; and a liquid-repellent layer on a lower surface of the second oxide layer in the first to third areas.

According to embodiments of the present disclosure, some layers of an inkjet head included in an inkjet printing apparatus may be damaged in an ink ejection process, and a process of regenerating the damaged inkjet head may be performed in order to reuse the damaged inkjet head. According to some embodiments, the regeneration process may include forming a first oxide layer, a second oxide layer, and a liquid-repellent layer on the damaged layers. According to some embodiments, the first oxide layer may unify the surface properties of the damaged layers, and the second oxide layer may strengthen the adhesion between the first oxide layer and the liquid-repellent layer.

As the damaged layers are delaminated and/or worn away in the ink ejection process, step differences may be formed in the damaged layers. The first oxide layer and the second oxide layer may alleviate the step differences of the damaged layers. As the first oxide layer and the second oxide layer alleviate the step differences, the liquid-repellent layer may be formed relatively flat. Accordingly, damage to the liquid-repellent layer in the ink ejection process may be prevented or reduced, and the durability of the inkjet head may be relatively improved.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an inkjet printing apparatus according to some embodiments of the present disclosure.

FIG. 2 is a plan view illustrating the inkjet printing apparatus of FIG. 1.

FIG. 3 is a plan view illustrating an inkjet head included in the inkjet printing apparatus of FIG. 1.

FIG. 4 is a cross-sectional view illustrating a head part of the inkjet head of FIG. 3.

FIG. 5 is an enlarged cross-sectional view of the area A of FIG. 4.

FIGS. 6, 7, 8, 9, 10, 11, 12, 13, and 14 are views illustrating an inkjet printing method according to some embodiments of the present disclosure.

FIG. 15 is a block diagram of an electronic device according to some embodiments of the present disclosure.

FIG. 16 is a schematic view of an electronic device according to various embodiments.

### DETAILED DESCRIPTION

Hereinafter, aspects of some embodiments of the present disclosure will be described in more detail with reference to the accompanying drawings. The same reference numerals are used for the same components in the drawings, and some redundant descriptions of the same components may be omitted.

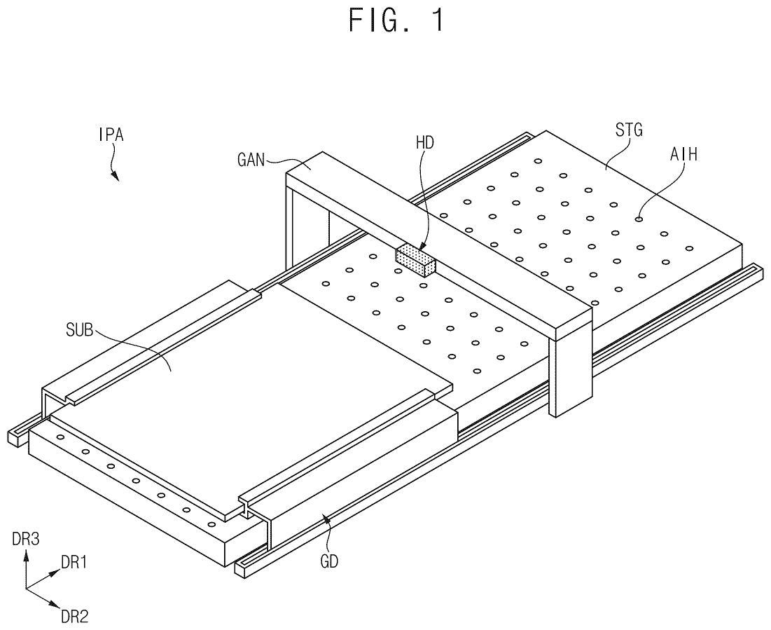

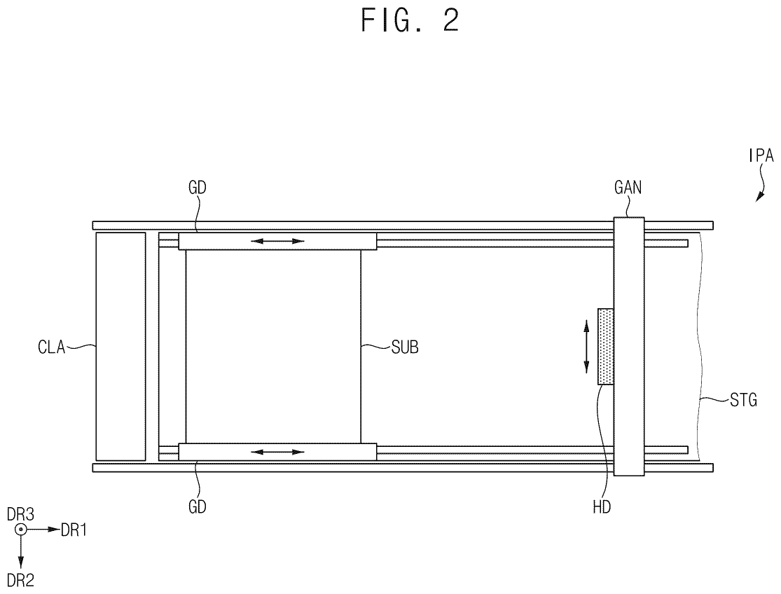

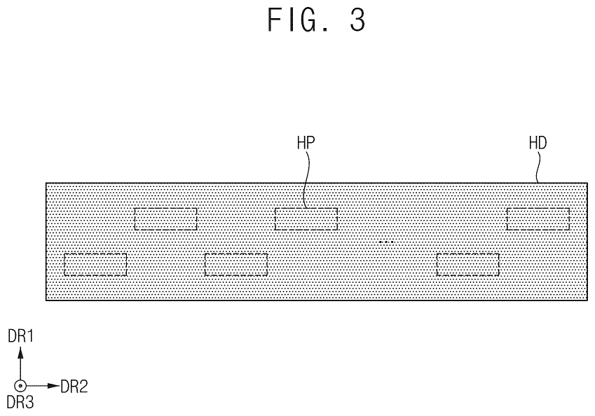

FIG. 1 is a perspective view illustrating an inkjet printing apparatus according to some embodiments of the present disclosure. FIG. 2 is a plan view illustrating the inkjet printing apparatus of FIG. 1. FIG. 3 is a plan view illustrating an inkjet head included in the inkjet printing apparatus of FIG. 1.

In this specification, a plane may be defined by a first direction DR1 and a second direction DR2 intersecting the first direction DR1. For example, the first direction DR1 and the second direction DR2 may be perpendicular to each other. A direction normal to the plane may be a third direction DR3. In other words, the third direction DR3 may be perpendicular to each of the first direction DR1 and the second direction DR2. As used herein the “plan view” is a view in the third direction DR3.

Referring to FIGS. 1, 2, and 3, an inkjet printing apparatus IPA according to some embodiments of the present disclosure may include a stage STG, an inkjet head HD, a gantry GAN, a guide part GD, and a cleaning part CLA. For example, the inkjet printing apparatus IPA may form an alignment film or apply an UV ink on a substrate SUB in a process of manufacturing a liquid crystal display device. For example, the inkjet printing apparatus IPA may apply an ink including an organic light-emitting material on a substrate SUB in a process of manufacturing an organic light-emitting display device. According to some embodiments, the inkjet printing apparatus IPA may apply an ink including a quantum dot ink composition on a substrate SUB.

The substrate SUB may be an object on which an ink is ejected. For example, the substrate SUB may be a substrate included an inorganic light-emitting display device that includes an inorganic light-emitting diode, an organic light-emitting display device that includes an organic light-emitting diode, a quantum dot light-emitting display device that includes a quantum dot light-emitting element, or the like.

The substrate SUB may be loaded on the stage STG. For example, the stage STG may have a flat (or a substantially flat) upper surface. According to some embodiments, the stage STG may include an electrostatic chuck that fixes and adsorbs the substrate SUB by electrostatic force. However, embodiments according to the present disclosure are not necessarily limited thereto. According to some embodiments, a plurality of air holes AIH may be formed on the upper surface of the stage STG. The air holes AIH may be holes that penetrate the stage STG in a thickness direction (e.g., the third direction DR3). Air may be sprayed from the air holes AIH toward the substrate SUB, and the substrate SUB may be levitated at a distance (e.g., a set or predetermined distance) from the stage STG.

The gantry GAN may be positioned on the stage STG. A space in which the inkjet head HD is located may be defined in the gantry GAN. The inkjet head HD may be located in the space of the gantry GAN, and may move in the second direction DR2 or in an opposite direction of the second direction DR2. The gantry GAN may transport the inkjet head HD in the first direction (DR1) or in an opposite direction of the first direction DR1. Accordingly, the gantry GAN may transport the inkjet head HD towards the cleaning part CLA.

The guide part GD may be positioned at a side portion of the stage STG. The guide part GD may transport the substrate SUB in the first direction DR1 or in the opposite direction of the first direction DR1. For example, the guide part GD may move in the first direction DR1 or in the opposite direction of the first direction DR1 while gripping the substrate SUB. Accordingly, the guide part GD may transport the substrate SUB toward the inkjet head HD.

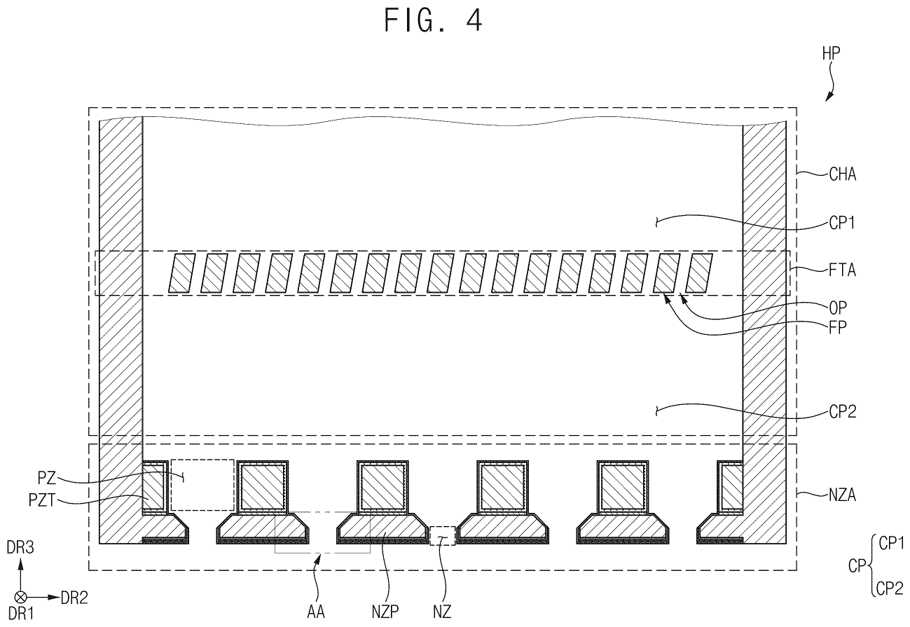

The cleaning part CLA may be positioned at one side of the stage STG. For example, the cleaning part CLA and the stage STG may be adjacent to each other in the first direction DR1. The cleaning part CLA may clean a foreign substance adsorbed near nozzle parts (NZ, see FIG. 4) of the inkjet head HD. For example, the cleaning part CLA may remove the foreign substance by wiping the inkjet head HD using a wiper. For another example, the cleaning part CLA may spray a fluid (e.g., an inert gas) in the third direction DR3 toward the inkjet head HD. For still another example, the cleaning part CLA may suck a fluid in an opposite direction of the third direction DR3.

The inkjet head HD may be positioned on the stage STG. The inkjet head HD may be coupled to a driving unit. The driving unit may raise and lower the inkjet head HD. For example, the driving unit may move the inkjet head HD in the third direction DR3 or in the opposite direction of the third direction DR3.

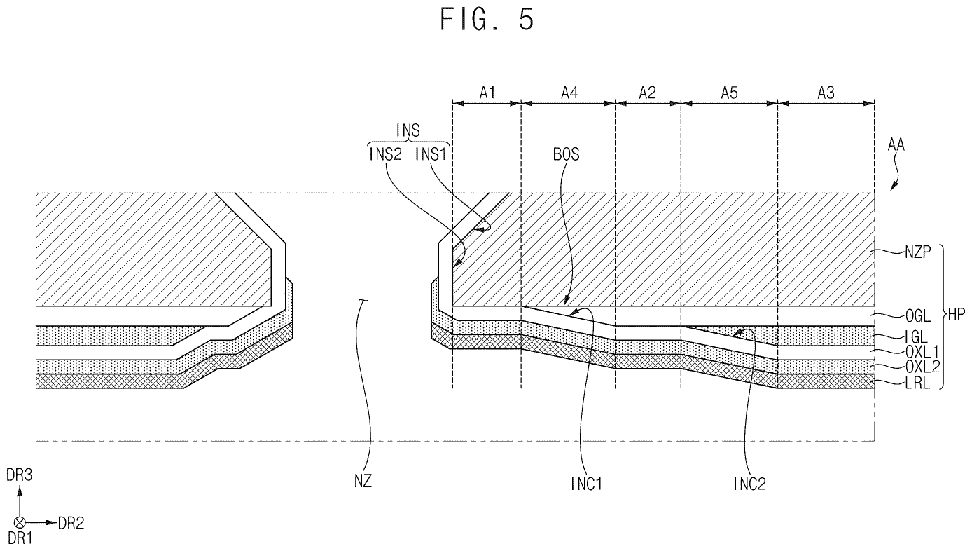

As illustrated in FIG. 3, the inkjet head HD may include a plurality of head parts HP. The head parts HP may be located at a surface of the inkjet head HD. For example, the head parts HP may be located at a lower surface of the inkjet head HD. The head parts HP may be spaced apart from each other. Each of the head parts HP may define nozzle parts from which an ink is ejected. A further detailed description thereof will be described below with reference to FIGS. 4 and 5.

The head parts HP may be arranged in a parallel manner along a direction. For example, the head parts HP may be arranged in a parallel manner along the second direction DR2. As illustrated in FIG. 3, the head parts HP may be arranged in two rows, but embodiments according to the present disclosure are not necessarily limited thereto. The head parts HP may be arranged in one row or in three or more rows, and the number of head parts HP may be varied according to embodiments.

The ink ejected by the head part HP may be a liquid including various substances. According to some embodiments, the ink may be an organic light-emitting ink for forming a pixel included in the display device. In this case, the organic light-emitting ink may be an ink in which an organic light-emitting material and a solvent are mixed. The organic light-emitting material may emit red light, green light, blue light, or the like when a voltage is applied. The solvent may be a substance that dissolves the organic light-emitting material, and may be readily mixed with the organic light-emitting material.

According to some embodiments, the ink may include a quantum dot ink composition. For example, the ink may include a quantum dot ink composition including zinc (Zn), but embodiments according to the present disclosure are not necessarily limited thereto.

FIG. 4 is a cross-sectional view illustrating a head part of the inkjet head of FIG. 3. FIG. 5 is an enlarged cross-sectional view of the area A of FIG. 4. For example, FIG. 5 is a cross-sectional view illustrating a portion of a nozzle area NZA of FIG. 4.

Referring to FIG. 4, according to some embodiments, the head part HP may include a chamber part CP, a filter part FP, a piezoelectric element part PZT, a nozzle plate NZP, and a plurality of functional layers surrounding the nozzle plate NZP.

The head part HP may include a chamber area CHA, a filter area FTA, and a nozzle area NZA. The chamber area CHA may be positioned between an ink supply part and the nozzle area NZA. The ink supply part may store an ink and may supply the ink to the head part HP. The chamber area CHA may be an area where the ink provided by the ink supply part is stored. The filter area FTA may be positioned inside the chamber area CHA. The filter area FTA may be an area that selectively transmits a specific particle in the ink. The nozzle area NZA may be positioned between the chamber area CHA and the substrate (SUB, see FIG. 1). The nozzle area NZA may be an area where the ink is ejected.

The chamber part CP may be located in the chamber area CHA. The chamber part CP may receive the ink from the ink supply part and may transfer the ink to the nozzle area NZA. That is, the chamber part CP may provide a passage through which the ink moves. In addition, the chamber part CP may provide an ink that is not ejected from the nozzle area NZA back to the ink supply part. The chamber part CP may be a part where the ink provided from the ink supply part is stored. The chamber part CP may include a first chamber part CP1 and a second chamber part CP2.

The first chamber part CP1 may be located between the ink supply part and the second chamber part CP2. The first chamber part CP1 may receive the ink from the ink supply part and may flow the ink toward the nozzle area NZA. A portion of the ink flowing into the first chamber part CP1 may pass through the filter part FP and move to the second chamber part CP2.

The filter part FP may be located in the filter area FTA. The filter part FP may be located between the first chamber part CP1 and the second chamber part CP2. The filter part FP may include a metal mesh layer. For example, the metal mesh layer may include stainless steel (SUS), but embodiments according to the present disclosure are not necessarily limited thereto.

The filter part FP may define a plurality of openings OP. The filter part FP may selectively pass (or permeate) a specific particle in the ink. That is, when the ink flowing into the first chamber part CP1 flows into the nozzle part NZ positioned in the nozzle area NZA, the filter part FP may prevent or reduce contaminants or other substances (or a foreign substance) except for the specific particle from flowing into the nozzle area NZA. According to some embodiments, the filter part FP may be omitted.

The second chamber part CP2 may be located between the first chamber part CP1 and the nozzle plate NZP. A portion of the ink that passed through the opening OP of the filter part FP may be ejected through the nozzle part NZ via the second chamber part CP2.

The nozzle plate NZP may be located in the nozzle area NZA. The nozzle plate NZP may be located on the stage (STG, see FIG. 1). The nozzle plate NZP may be located between the chamber part CP and the stage. The nozzle plate NZP may define a plurality of nozzle parts NZ. The nozzle parts NZ may be spaced apart from each other. Each of the nozzle parts NZ may be a portion of the head part HP ejecting the ink. That is, each of the nozzle parts NZ may eject the ink provided from the first chamber part CP1 and the second chamber part CP2.

The piezoelectric element parts PZT may be located in the nozzle area NZA. The piezoelectric element parts PZT may be adjacent to the nozzle parts NZ, respectively. The piezoelectric element parts PZT may be spaced apart from each other. According to some embodiments, the head part HP may further include an organic film surrounding the piezoelectric element parts PZT. For example, the organic film may entirely surround the piezoelectric element parts PZT.

A spaced area between the piezoelectric element parts PZT may be defined as a piezoelectric element area PZ. The piezoelectric element area PZ may be positioned inside the nozzle area NZA. For example, the piezoelectric element area PZ may be positioned between the chamber part CP and the nozzle part NZ. The amount of ink ejected through each nozzle part NZ may be controlled by the piezoelectric element part PZT. That is, the piezoelectric element part PZT may control a pressure applied to the piezoelectric element area PZ according to a voltage applied to the piezoelectric element part PZT. When the pressure is applied to the piezoelectric element area PZ, an ink in the piezoelectric element area PZ may be ejected onto the substrate through the nozzle part NZ.

Referring further to FIG. 5, the head part HP may include the nozzle plate NZP and a plurality of functional layers located on the nozzle plate NZP. The functional layers may include an organic layer OGL, an inorganic layer IGL, a first oxide layer OXL1, a second oxide layer OXL2, and a liquid-repellent layer LRL.

The nozzle plate NZP may include first to fifth areas A1, A2, A3, A4, and A5. The first area A1 may be adjacent to the nozzle part NZ. The second area A2 may be adjacent to the first area A1 in a direction away from the nozzle part NZ. The third area A3 may be adjacent to the second area A2 in the direction away from the nozzle part NZ. The fourth area A4 may be positioned between the first area A1 and the second area A2. The fifth area A5 may be positioned between the second area A2 and the third area A3. In summary, the first to fifth areas A1, A2, A3, A4, and A5 may be arranged in an order of the first area A1, the fourth area A4, the second area A2, the fifth area A5, and the third area A3 in the direction away from the nozzle part NZ with respect to the nozzle part NZ.

For example, the nozzle plate NZP may include an organic material such as polyimide (PI) or a metal such as stainless steel (SUS), iron (Fe), chromium (Cr), nickel (Ni), or the like.

The nozzle plate NZP may have an inner side surface INS defining the nozzle part NZ and a lower surface BOS facing the stage (STG, see FIG. 1). The inner side surface INS may include a first inner side surface INS1 and a second inner side surface INS2. The first inner side surface INS1 may be inclined with respect to the lower surface BOS. The second inner side surface INS2 may be connected to the first inner side surface INS1 and the lower surface BOS. The second inner side surface INS2 may be perpendicular to the lower surface BOS. That is, the second inner side surface INS2 may extend in a thickness direction (e.g., the third direction DR3) of the head part HP.

The nozzle part NZ may include a first portion defined by the first inner side surface INS1 and a second portion defined by the second inner side surface INS2. A diameter (e.g., a length in the second direction DR2) of the first portion of the nozzle part NZ may decrease as it approaches the second inner side surface INS2. The second portion of the nozzle part NZ may have a constant diameter. An average diameter of the first portion of the nozzle part NZ may be greater than an average diameter of the second portion of the nozzle part NZ. Accordingly, an ink moving from the first portion of the nozzle part NZ to the second portion of the nozzle part NZ may be ejected toward the substrate (SUB, see FIG. 1) under relatively high pressure. That is, the nozzle part NZ may form a bottleneck structure by the first inner side surface INS1 and the second inner side surface INS2. For example, the nozzle part NZ may have a circular cross-sectional shape, but embodiments according to the present disclosure are not necessarily limited thereto.

The organic layer OGL may be located on the lower surface BOS of the nozzle plate NZP in the second area A2 and the third area A3. The organic layer OGL may be spaced apart from the first area A1 in a plan view. In other words, the organic layer OGL may not contact the nozzle plate NZP in the first area A1.

According to some embodiments, the organic layer OGL may be further located on the lower surface BOS of the nozzle plate NZP in the fourth area A4 and the fifth area A5. The organic layer OGL may have a flat lower surface in the fifth area A5. The organic layer OGL may have a first inclined surface INC1 that is inclined with respect to the lower surface BOS of the nozzle plate NZP in the fourth area A4. In other words, a step difference may be formed in the organic layer OGL.

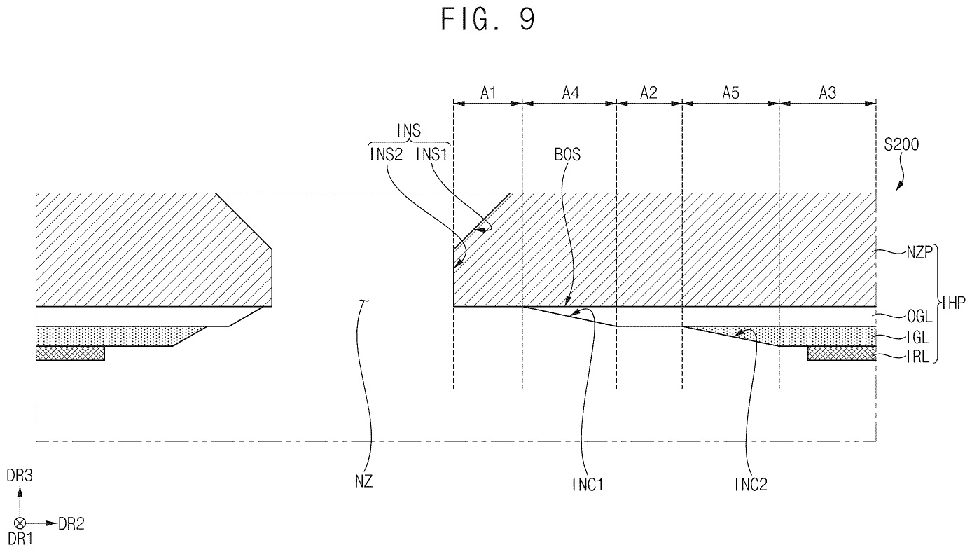

At least a portion of the organic layer OGL may be damaged by a particle included in an ink during an ink ejection process. For example, after the ink ejection process, a portion of the organic layer OGL overlapping the first area A1 may be removed (or delaminated). For example, after the ink ejection process, a portion of the organic layer OGL overlapping the fourth area A4 may be worn away, and the step difference in the organic layer OGL may be formed. A detailed description thereof will be described below with reference to FIG. 9.

The organic layer OGL may include an organic material. According to some embodiments, the organic layer OGL may include parylene. For example, the organic layer may include C-type parylene (parylene C). However, embodiments according to the present disclosure are not necessarily limited thereto. For example, the organic layer OGL may be formed on the lower surface BOS of the nozzle plate NZP through a chemical vapor deposition (CVD) process.

The inorganic layer IGL may be located on the lower surface of the organic layer OGL in the third area A3. The inorganic layer IGL may be spaced apart from the first area A1 and the second area A2 in a plan view. In other words, the inorganic layer IGL may not contact the nozzle plate NZP in the first area A1 and may not contact the organic layer OGL in the second area A2. In addition, the inorganic layer IGL may be spaced apart from the fourth area A4 in a plan view. In other words, the inorganic layer IGL may not contact the organic layer OGL in the fourth area A4.

According to some embodiments, the inorganic layer IGL may be further located on the lower surface of the organic layer OGL in the fifth area A5. The inorganic layer IGL may have a second inclined surface INC2 that is inclined with respect to the lower surface BOS of the nozzle plate NZP (or the lower surface of the organic layer OGL) in the fifth area A5. In other words, a step difference may be formed in the inorganic layer IGL.

At least a portion of the inorganic layer IGL may be damaged by a particle included in an ink during the ink ejection process. For example, after the ink ejection process, a portion of the inorganic layer IGL overlapping the first area A1, the fourth area A4, and the second area A2 may be removed (or delaminated). For example, after the ink ejection process, a portion of the inorganic layer IGL overlapping the fifth area A5 may be worn away, and the step difference in the inorganic layer IGL may be formed. A detailed description thereof will be described below with reference to FIG. 9.

According to some embodiments, the inorganic layer IGL may include silicon oxycarbide (SiOC). That is, the inorganic layer IGL may be a SiOC thin film in which silicon oxide (SiOₓ) includes some carbon (C). For example, the inorganic layer IGL may be formed on the lower surface of the organic layer OGL through a physical vapor deposition (PVD) process or a sputtering process.

The first oxide layer OXL1 may be located on the lower surface BOS of the nozzle plate NZP in the first to third areas A1, A2, and A3. In addition, the first oxide layer OXL1 may be further located on the lower surface BOS of the nozzle plate NZP in the fourth area A4 and the fifth area A5. The first oxide layer OXL1 may cover the nozzle plate NZP, the organic layer OGL, and the inorganic layer IGL.

According to some embodiments, the first oxide layer OXL1 may cover a first inclined surface INC1 of the organic layer OGL and a second inclined surface INC2 of the inorganic layer IGL. That is, the first oxide layer OXL1 may alleviate the step difference of the organic layer OGL and the step difference of the inorganic layer IGL. According to some embodiments, the first oxide layer OXL1 may be arranged along the profiles of the lower surface of the organic layer OGL, the first inclined surface INC1, a lower surface of the inorganic layer IGL, and the second inclined surface INC2.

According to some embodiments, the first oxide layer OXL1 may entirely cover the inner side surface INS of the nozzle plate NZP. That is, the first oxide layer OXL1 may be arranged further on the inner side surface INS of the nozzle plate NZP. According to some embodiments, the first oxide layer OXL1 may extend to the piezoelectric element part PZT. That is, the first oxide layer OXL1 may cover the piezoelectric element part PZT. For example, the first oxide layer OXL1 may entirely cover the piezoelectric element part PZT.

According to some embodiments, the first oxide layer OXL1 may include an aluminum oxide (AlₓO_{y}). For example, the first oxide layer OXL1 may include Al₂O₃. The first oxide layer OXL1 may unify the surface property of the nozzle plate NZP, the surface property of the organic layer OGL, and the surface property of the inorganic layer IGL. That is, the first oxide layer OXL1 may unify the surface characteristics of the nozzle plate NZP, the organic layer OGL, and the inorganic layer IGL such that a lower structure (e.g., the second oxide layer OXL2 and the liquid-repellent layer LRL) may be easily deposited under the first oxide layer OXL1.

For example, the first oxide layer OXL1 may be formed through an atomic layer deposition (ALD) process, a physical vapor deposition (PVD) process, or a sputtering process. According to some embodiments, the first oxide layer OXL1 may be deposited in the form of a thin film through an ALD process.

The second oxide layer OXL2 may be located on a lower surface of the first oxide layer OXL1 in the first to third areas A1, A2, and A3. In addition, the second oxide layer OXL2 may be further located on the lower surface of the first oxide layer OXL1 in the fourth area A4 and the fifth area A5. The second oxide layer OXL2 may cover the nozzle plate NZP, the organic layer OGL, and the inorganic layer IGL.

According to some embodiments, the second oxide layer OXL2 may cover the first inclined surface INC1 of the organic layer OGL and the second inclined surface INC2 of the inorganic layer IGL. That is, the second oxide layer OXL2 may alleviate the step difference of the organic layer OGL and the step difference of the inorganic layer IGL. According to some embodiments, the second oxide layer OXL2 may be arranged along the profile of the lower surface of the first oxide layer OXL1.

According to some embodiments, the second oxide layer OXL2 may extend only to a portion of the inner side surface INS of the nozzle plate NZP. For example, the second oxide layer OXL2 may cover a portion of the second inner side surface INS2 and may not cover the first inner side surface INS1.

According to some embodiments, the second oxide layer OXL2 may include silicon oxide (SiOₓ). For example, the second oxide layer OXL2 may include SiO₂. The second oxide layer OXL2 may strengthen the adhesion between the first oxide layer OXL1 and the liquid-repellent layer LRL. For example, the second oxide layer OXL2 may be formed through an atomic layer deposition (ALD) process, a physical vapor deposition (PVD) process, or a sputtering process.

The liquid-repellent layer LRL may be located on a lower surface of the second oxide layer OXL2 in the first to third areas A1, A2, and A3. In addition, the liquid-repellent layer LRL may be further located on the lower surface of the second oxide layer OXL2 in the fourth area A4 and the fifth area A5. According to some embodiments, the liquid-repellent layer LRL may be arranged along the profile of the lower surface of the second oxide layer OXL2. According to some embodiments, the liquid-repellent layer LRL may not cover the inner side surface INS of the nozzle plate NZP.

As the first oxide layer OXL1 and the second oxide layer OXL2 alleviate the step difference of the organic layer OGL and the step difference of the inorganic layer IGL, the liquid-repellent layer LRL may be relatively flatly located under the nozzle plate NZP (e.g., under the second oxide layer OXL2). Accordingly, damage (e.g., delamination) to the liquid-repellent layer LRL during the ink ejection process may be prevented or reduced.

The liquid-repellent layer LRL may include a liquid-repellent material. For example, the liquid-repellent layer LRL may include a fluorine-based compound or a siloxane-based compound. According to some embodiments, the liquid-repellent layer LRL may include a per-and polyfluoroalkyl substance (PFAS). The liquid-repellent material may be positioned at a surface of the liquid-repellent layer LRL. In other words, the liquid-repellent material may cover the surface of the liquid-repellent layer LRL, and the surface of the liquid-repellent layer LRL may have a liquid-repellent property.

As the surface of the liquid-repellent layer LRL has a liquid-repellent property, a contact angle between the ink ejected through the nozzle portion NZ and the liquid-repellent layer LRL may be increased. That is, the binding force between the ink and the liquid-repellent layer LRL may be decreased. Accordingly, the ink may not be adsorbed to the liquid-repellent layer LRL and may be ejected to the outside of the head part HP.

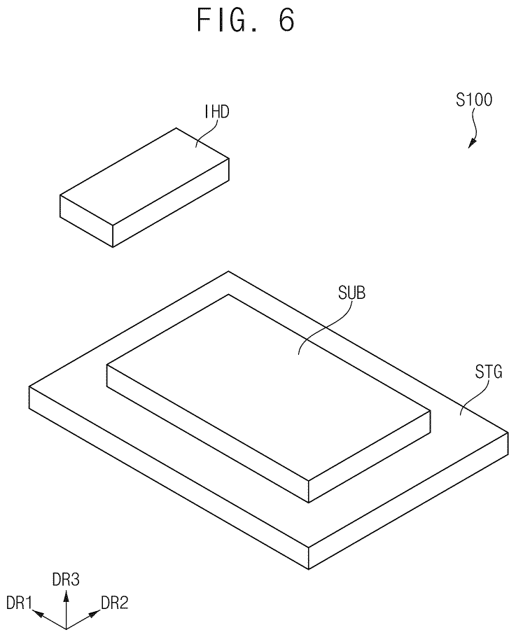

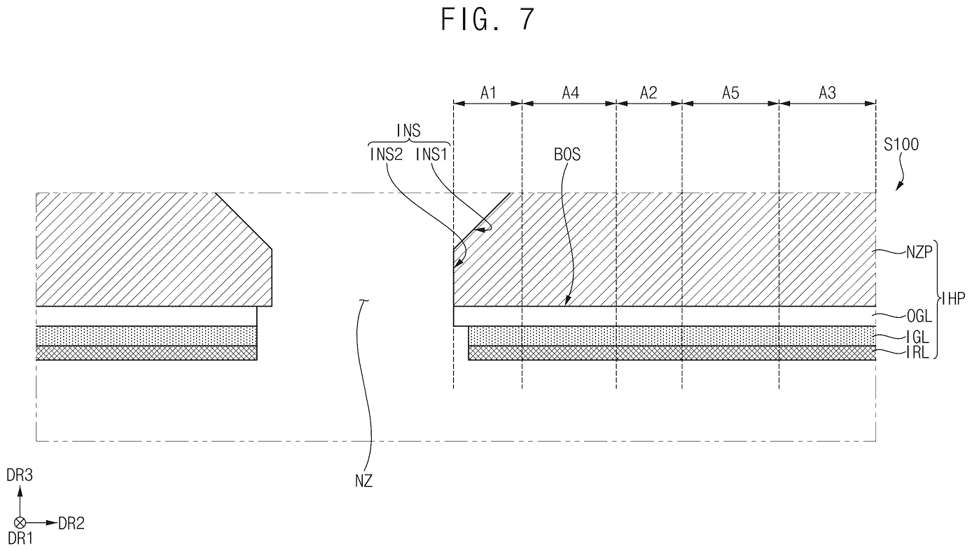

FIGS. 6, 7, 8, 9, 10, 11, 12, 13, and 14 are views illustrating an inkjet printing method according to some embodiments of the present disclosure. For example, FIGS. 6, 8, and 14 are perspective views for describing the inkjet printing method. For example, FIGS. 7, 9, 10, 11, 12, and 13 are cross-sectional views for describing the inkjet printing method. Hereinafter, some redundant descriptions of the head part HP described above with reference to FIGS. 4 and 5 may be omitted or summarized.

Referring to FIGS. 6 and 7, the stage STG and an initial inkjet head IHD positioned on the stage STG may be prepared (S100). The substrate SUB may be loaded onto the stage STG. The substrate SUB may be an object where an ink is ejected.

The initial inkjet head IHD may include a plurality of initial head parts IHP. The initial head parts IHP may be located at a surface of the initial inkjet head IHD. For example, the initial head parts IHP may be located at a lower surface of the initial inkjet head IHD. Each of the initial head parts IHP may define nozzle parts NZ that eject the ink.

According to some embodiments, the ink ejected by the initial head part IHP may be an ink including a particle. For example, the ink may include a quantum dot ink composition.

As illustrated in FIG. 7, the initial head part IHP may include a nozzle plate NZP, an organic layer OGL, an inorganic layer IGL, and an initial liquid-repellent layer IRL.

The nozzle plate NZP may include the first to fifth areas A1, A2, A3, A4, and A5. The first to fifth areas A1, A2, A3, A4, and A5 may be arranged in the order of the first area A1, the fourth area A4, the second area A2, the fifth area A5, and the third area A3 in a direction away from the nozzle part NZ with respect to the nozzle part NZ.

The nozzle plate NZP may have the inner side surface INS defining the nozzle part NZ and the lower surface BOS facing the stage STG.

The organic layer OGL may be located on the lower surface BOS of the nozzle plate NZP in the first to fifth areas A1, A2, A3, A4, and A5. That is, before the ink ejection process, the organic layer OGL may contact the nozzle plate NZP in the first to fifth areas A1, A2, A3, A4, and A5. According to some embodiments, the organic layer OGL may include parylene. For example, the organic layer OGL may include C-type parylene (parylene C).

The inorganic layer IGL may be located on a lower surface of the organic layer OGL in the first to fifth areas A1, A2, A3, A4, and A5. That is, before the inkjet ejection process, the inorganic layer IGL may contact the organic layer OGL in the first to fifth areas A1, A2, A3, A4, and A5. According to some embodiments, the inorganic layer IGL may include silicon oxycarbide (SiOC). Accordingly, the inorganic layer IGL may strengthen the adhesion between the organic layer OGL and the initial liquid-repellent layer IRL.

The initial liquid-repellent layer IRL may be located on a lower surface of the inorganic layer IGL in the first to fifth areas A1, A2, A3, A4, and A5. That is, before the ink ejection process, the initial liquid-repellent layer IRL may contact the inorganic layer IGL in the first to fifth areas A1, A2, A3, A4, and A5. The initial liquid-repellent layer IRL may include a liquid-repellent material.

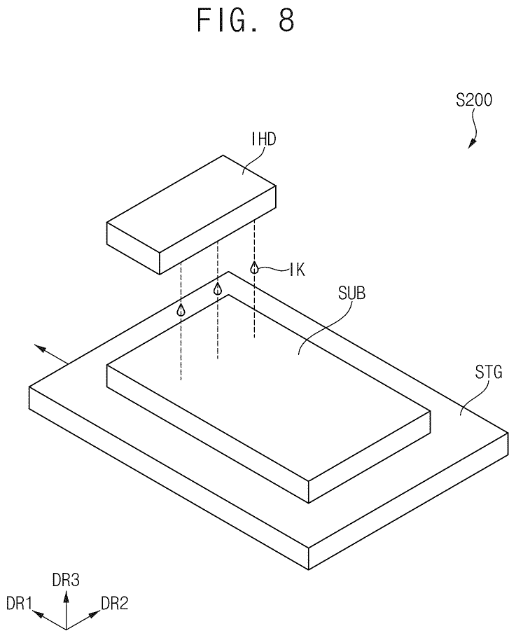

Referring to FIG. 8, Referring to FIG. 8, the substrate SUB may be transported toward the initial inkjet head IHD, and the initial inkjet head IHD may eject the ink IK onto the substrate SUB (S200).

As the stage STG moves in the first direction DR1, the substrate SUB may be transported in the first direction DR1 toward the initial inkjet head IHD. Accordingly, the substrate SUB may move under the initial inkjet head IHD, and the initial inkjet head IHD may eject the ink IK onto the substrate SUB.

According to some embodiments, after the process of ejecting the ink IK, a process of cleaning a foreign substance adsorbed near the nozzle part may be performed using the cleaning part (CLA, see FIG. 2).

Referring further to FIG. 9, as the process of ejecting the ink IK is repeatedly performed, the initial head part IHP of the initial inkjet head IHD may be damaged. For example, when the ink IK includes a quantum dot ink composition, a portion of the initial head part IHP may be damaged (e.g., delaminated or worn) by a particle included in the ink IK during the process of ejecting the ink IK.

At least a portion of the organic layer OGL may be damaged in the process of ejecting the ink IK. For example, after the process of ejecting the ink IK, a portion of the organic layer OGL overlapping the first area A1 may be removed (or delaminated), and a portion of the organic layer OGL overlapping the fourth area A4 may be worn away. Accordingly, the organic layer OGL may remain on the lower surface BOS of the nozzle plate NZP in the second area A2, the fifth area A5, and the third area A3, and the first inclined surface INC1 may be formed in the fourth area A4. That is, the step difference may be formed in the organic layer OGL. The organic layer OGL may be spaced apart from the first area A1 in a plan view.

In addition, at least a portion of the inorganic layer IGL may be damaged in the process of ejecting the ink IK. For example, after the process of ejecting the ink IK, a portion of the inorganic layer IGL overlapping the first area A1, the fourth area A4, and the second area A2 may be removed (or delaminated), and a portion of the inorganic layer IGL overlapping the fifth area A5 may be worn away. Accordingly, the inorganic layer IGL may remain on the lower surface of the organic layer OGL in the third area A3, and the second inclined surface INC2 may be formed in the fifth area A5. That is, the step difference may be formed in the inorganic layer IGL. The inorganic layer IGL may be spaced apart from the first area A1, the fourth area A4, and the second area A2 in a plan view.

In addition, at least a portion of the initial liquid-repellent layer IRL may be damaged in the process of ejecting the ink IK. For example, after the process of ejecting the ink IK, a portion of the initial liquid-repellent layer IRL overlapping the first area A1, the fourth area A4, the second area A2, and the fifth area A5 may be removed (or delaminated). Accordingly, the initial liquid-repellent layer IRL may remain on the lower surface of the inorganic layer IGL in the third area A3. The initial liquid-repellent layer IRL may be spaced apart from the first area A1, the fourth area A4, the second area A2, and the fifth area A5 in a plan view. When the portion of the initial liquid-repellent layer IRL is removed (or delaminated), the ink IK ejected by the initial head part IHP may not be ejected to a target location.

Referring to FIGS. 9, 10, 11, 12, and 13, in order to prevent or reduce instances of a problem in which the ink is not ejected to the target location, a process of forming the head part HP may be performed by regenerating the initial head part IHP.

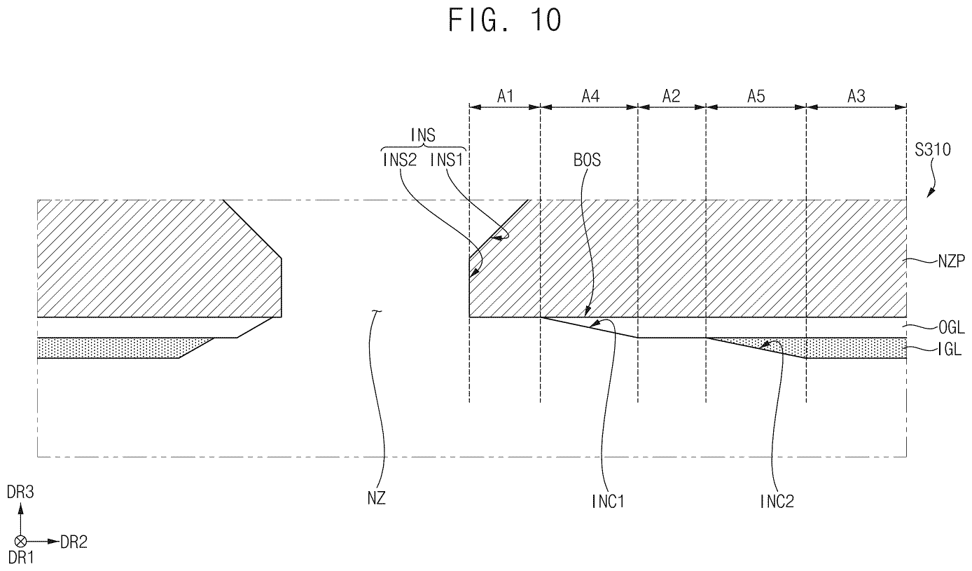

As illustrated in FIG. 10, the initial liquid-repellent layer IRL positioned on the lower surface of the inorganic layer IGL may be removed (S310); that is, the initial liquid-repellent layer IRL that is damaged during the ink ejection process may be removed.

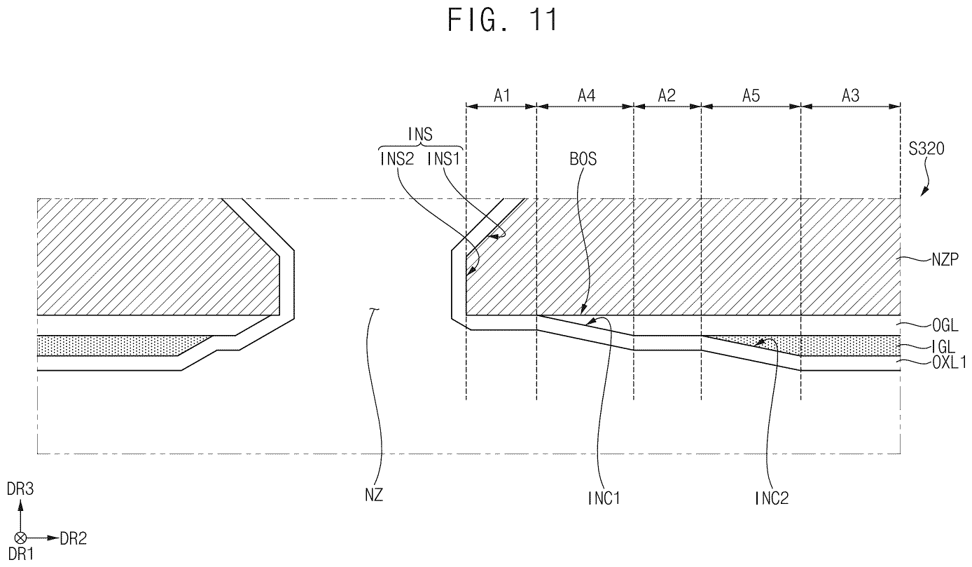

As illustrated in FIG. 11, the first oxide layer OXL1 may be formed on the lower surface BOS of the nozzle plate NZP in the first to third areas A1, A2, and A3 (S320). In addition, the first oxide layer OXL1 may be further formed on the lower surface BOS of the nozzle plate NZP in the fourth area A4 and the fifth area A5. The first oxide layer OXL1 may cover the nozzle plate NZP, the organic layer OGL, and the inorganic layer IGL.

According to some embodiments, the first oxide layer OXL1 may cover the first inclined surface INC1 of the organic layer OGL and the second inclined surface INC2 of the inorganic layer IGL. That is, the first oxide layer OXL1 may alleviate the step difference of the organic layer OGL and the step difference of the inorganic layer IGL. According to some embodiments, the first oxide layer OXL1 may be formed along the profiles of the lower surface of the organic layer OGL, the first inclined surface INC1, a lower surface of the inorganic layer IGL, and the second inclined surface INC2.

According to some embodiments, the first oxide layer OXL1 may include an aluminum oxide (AlₓO_{y}). For example, the first oxide layer OXL1 may include Al₂O₃.

For example, the first oxide layer OXL1 may be formed through an atomic layer deposition (ALD) process, a physical vapor deposition (PVD) process, or a sputtering process. According to some embodiments, the first oxide layer OXL1 may be deposited in the form of a thin film through an ALD process. In this case, the first oxide layer OXL1 may be formed to entirely cover the inner side surface INS of the nozzle plate NZP.

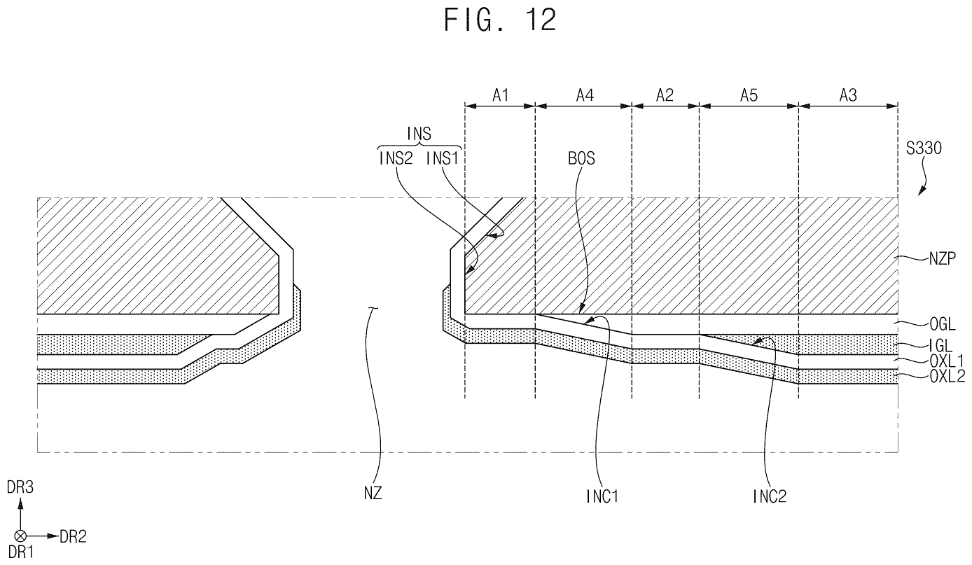

As illustrated in FIG. 12, the second oxide layer OXL2 may be formed on the lower surface of the first oxide layer OXL1 in the first to third areas A1, A2, and A3 (S320). In addition, the second oxide layer OXL2 may be further formed on the lower surface of the first oxide layer OXL1 in the fourth area A4 and the fifth area A5. The second oxide layer OXL2 may cover the nozzle plate NZP, the organic layer OGL, and the inorganic layer IGL.

According to some embodiments, the second oxide layer OXL2 may cover the first inclined surface INC1 of the organic layer OGL and the second inclined surface INC2 of the inorganic layer IGL. That is, the second oxide layer OXL2 may alleviate the step difference of the organic layer OGL and the step difference of the inorganic layer IGL. According to some embodiments, the second oxide layer OXL2 may be formed along the profile of the lower surface of the first oxide layer OXL1.

According to some embodiments, the second oxide layer OXL2 may be formed to extend only to a portion of the inner side surface INS of the nozzle plate NZP. For example, the second oxide layer OXL2 may cover a portion of the second inner side surface INS2 and may not cover the first inner side surface INS1.

According to some embodiments, the second oxide layer OXL2 may include silicon oxide (SiOₓ). For example, the second oxide layer OXL2 may include SiO₂. For example, the second oxide layer OXL2 may be formed through an atomic layer deposition (ALD) process, a physical vapor deposition (PVD) process, or a sputtering process.

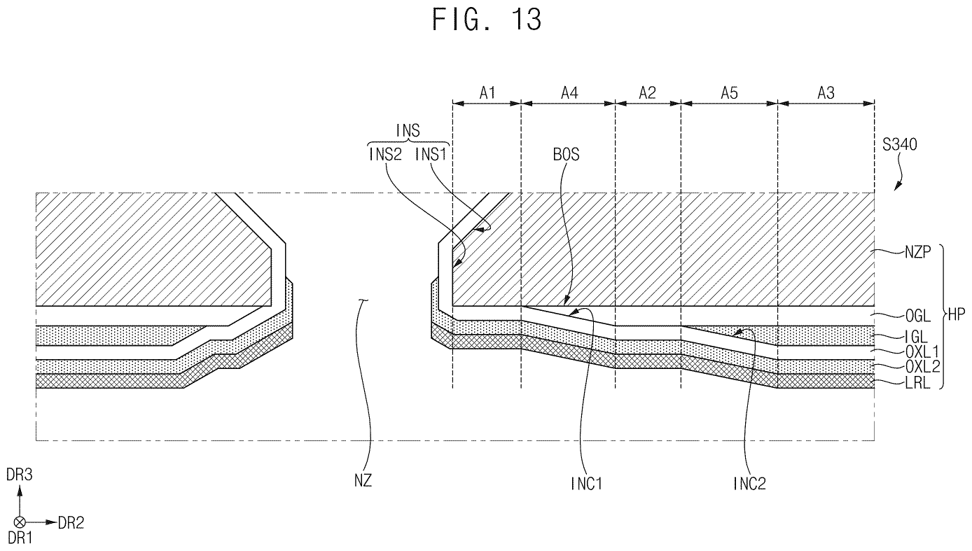

As illustrated in FIG. 13, the liquid-repellent layer LRL may be formed on a lower surface of the second oxide layer OXL2 in the first to third areas A1, A2, and A3 (S340). In addition, the liquid-repellent layer LRL may be further formed on the lower surface of the second oxide layer OXL2 in the fourth area A4 and the fifth area A5. According to some embodiments, the liquid-repellent layer LRL may be formed along the profile of the lower surface of the second oxide layer OXL2. According to some embodiments, the liquid-repellent layer LRL may not cover the inner side surface INS of the nozzle plate NZP.

The liquid-repellent layer LRL may include a liquid-repellent material. For example, the liquid-repellent layer LRL may include a fluorine-based compound or a siloxane-based compound. According to some embodiments, the liquid-repellent layer LRL may include a per-and polyfluoroalkyl substance (PFAS).

Accordingly, the head part HP including the nozzle plate NZP, the organic layer OGL, the inorganic layer IGL, the first oxide layer OXL1, the second oxide layer OXL2, and the liquid-repellent layer LRL may be formed.

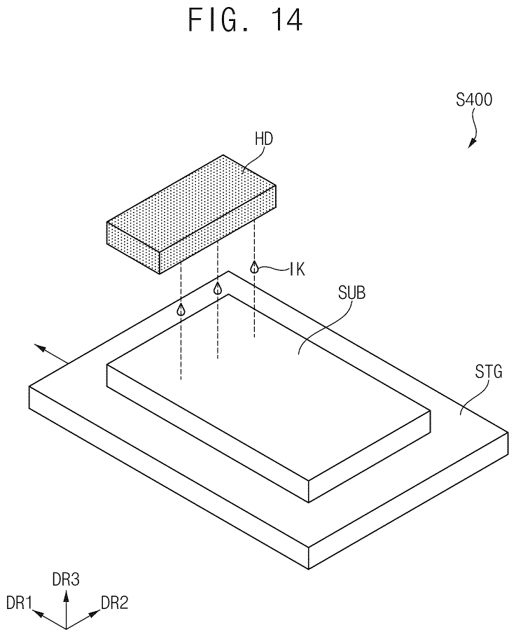

Referring further to FIG. 14, the ink IK may be ejected onto the substrate SUB using the inkjet head HD including the head part HP (S400). That is, after a damaged initial head part (IHP, see FIG. 9) is regenerated to form the head part HP, the process of ejecting the ink IK onto the substrate SUB may be performed again.

As the first oxide layer OXL1 and the second oxide layer OXL2 alleviate the step difference of the organic layer OGL and the step difference of the inorganic layer IGL, the liquid-repellent layer LRL may be relatively flatly formed under the nozzle plate NZP (e.g., under the second oxide layer OXL2). Accordingly, damage (e.g., delamination) to the liquid-repellent layer LRL in the process of ejecting the ink IK may be prevented or reduced, and the durability of the inkjet head HD may be relatively improved. In other words, the process of forming the head part HP by regenerating the initial head part IHP described above with reference to FIGS. 9 to 13 may be a process of relatively improving the durability of the inkjet head HD.

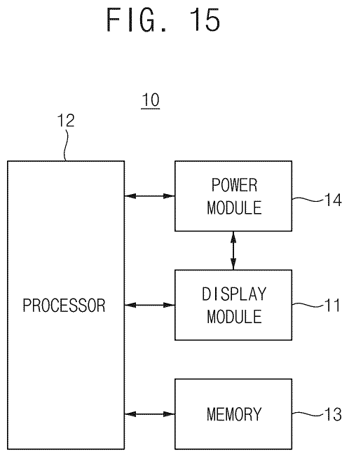

FIG. 15 is a block diagram of an electronic device according to some embodiments of the present disclosure.

Referring to FIG. 15, an electronic device 10 according to some embodiments may include a display module 11, a processor 12, a memory 13, and a power module 14. The display device including the substrate (SUB, see FIG. 1) on which ink ejected by the inkjet printing apparatus (IPA, see FIG. 1) is applied may be applied to a variety of electronic devices. The electronic device 10 according to some embodiments may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), or a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

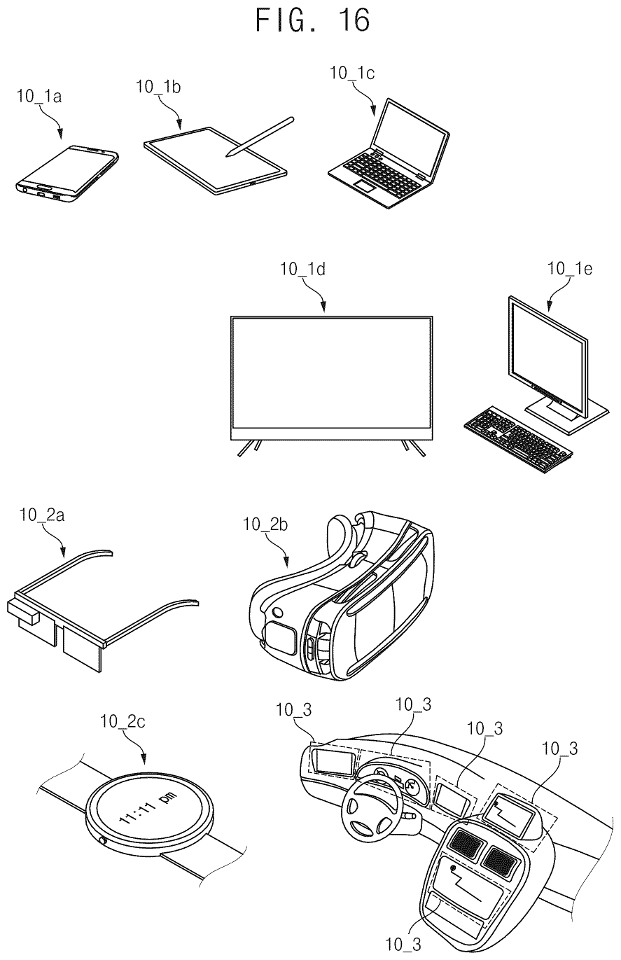

FIG. 16 is a schematic view of an electronic device according to various embodiments.

Referring to FIG. 16, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be located on an instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims, and their equivalents.

What is claimed is:

1. An inkjet printing apparatus comprising:
a stage on which a substrate is loaded; and
an inkjet head on the stage and comprising a head part,
wherein the head part comprises:
a nozzle plate having an inner side surface defining a nozzle part configured to eject an ink and a lower surface facing the stage, the nozzle plate comprising a first area, a second area, and a third area sequentially arranged in a direction away from the nozzle part with respect to the nozzle part;
an organic layer on the lower surface of the nozzle plate in the second area and the third area, and spaced apart from the first area in a plan view;
an inorganic layer on a lower surface of the organic layer in the third area and spaced apart from the first area and the second area in the plan view;
a first oxide layer on the lower surface of the nozzle plate in the first to third areas and covering the nozzle plate, the organic layer, and the inorganic layer;
a second oxide layer on a lower surface of the first oxide layer in the first to third areas; and
a liquid-repellent layer on a lower surface of the second oxide layer in the first to third areas.

2. The apparatus of claim 1, wherein the nozzle plate further comprises:
a fourth area between the first area and the second area; and
a fifth area between the second area and the third area.

3. The apparatus of claim 2,
wherein the organic layer is further on the lower surface of the nozzle plate in the fourth area and the fifth area, and
wherein the organic layer has a first inclined surface which is inclined with respect to the lower surface of the nozzle plate in the fourth area.

4. The apparatus of claim 3,
wherein the inorganic layer is further on the lower surface of the organic layer in the fifth area, and
wherein the inorganic layer has a second inclined surface which is inclined with respect to the lower surface of the nozzle plate in the fifth area.

5. The apparatus of claim 4, wherein the inorganic layer is spaced apart from the fourth area in the plan view.

6. The apparatus of claim 4,
wherein each of the first oxide layer and the second oxide layer is further on the lower surface of the nozzle plate in the fourth area and the fifth area, and
wherein each of the first oxide layer and the second oxide layer covers the first inclined surface and the second inclined surface.

7. The apparatus of claim 6,
wherein the first oxide layer is arranged along profiles of the lower surface of the organic layer, the first inclined surface, a lower surface of the inorganic layer, and the second inclined surface, and
wherein the second oxide layer is arranged along a profile of the lower surface of the first oxide layer.

8. The apparatus of claim 7, wherein the liquid-repellent layer is arranged along a profile of the lower surface of the second oxide layer.

9. The apparatus of claim 1, wherein the first oxide layer entirely covers the inner side surface of the nozzle plate.

10. The apparatus of claim 1, wherein the inorganic layer comprises silicon oxycarbide.

11. The apparatus of claim 1, wherein the first oxide layer comprises aluminum oxide.

12. The apparatus of claim 1, wherein the second oxide layer comprises silicon oxide.

13. An inkjet printing method, the method comprising:
providing an initial inkjet head comprising:
a nozzle plate which has an inner side surface defining a nozzle part configured to eject an ink and comprises a first area, a second area, and a third area sequentially arranged in a direction away from the nozzle part with respect to the nozzle part;
an organic layer on a lower surface of the nozzle plate in the second area and the third area, and spaced apart from the first area in a plan view;
an inorganic layer on a lower surface of the organic layer in the third area and spaced apart from the first area and the second area in the plan view; and
an initial liquid-repellent layer on a lower surface of the inorganic layer;
removing the initial liquid-repellent layer;
forming a first oxide layer covering the nozzle plate, the organic layer, and the inorganic layer on the lower surface of the nozzle plate in the first to third areas;
forming a second oxide layer on a lower surface of the first oxide layer in the first to third areas;
forming a liquid-repellent layer on a lower surface of the second oxide layer in the first to third areas, thereby forming an inkjet head comprising the nozzle plate, the organic layer, the inorganic layer, the first oxide layer, the second oxide layer, and the liquid-repellent layer; and
ejecting the ink onto a substrate using the inkjet head.

14. The method of claim 13, wherein the nozzle plate further comprises:
a fourth area between the first area and the second area; and
a fifth area between the second area and the third area.

15. The method of claim 14,
wherein the organic layer is further on the lower surface of the nozzle plate in the fourth area and the fifth area, and has a first inclined surface which is inclined with respect to the lower surface of the nozzle plate in the fourth area, and
wherein the inorganic layer is further on the lower surface of the organic layer in the fifth area, and has a second inclined surface which is inclined with respect to the lower surface of the nozzle plate in the fifth area.

16. The method of claim 15,
wherein each of the first oxide layer and the second oxide layer is further formed on the lower surface of the nozzle plate in the fourth area and the fifth area, and
wherein each of the first oxide layer and the second oxide layer covers the first inclined surface and the second inclined surface.

17. The method of claim 16,
wherein the first oxide layer is formed along profiles of the lower surface of the organic layer, the first inclined surface, the lower surface of the inorganic layer, and the second inclined surface, and
wherein the second oxide layer is formed along a profile of the lower surface of the first oxide layer.

18. The method of claim 17, wherein the liquid-repellent layer is formed along a profile of the lower surface of the second oxide layer.

19. The method of claim 13, wherein the first oxide layer entirely covers the inner side surface of the nozzle plate.

20. An electronic device comprising:
a display device comprising a substrate on which an ink ejected by an inkjet printing apparatus is applied; and
a processor configured to transmit an image data signal and an input control signal to the display device,
wherein the inkjet printing apparatus comprises:
a stage on which the substrate is loaded;
a nozzle plate having an inner side surface defining a nozzle part configured to eject the ink and a lower surface facing the stage, the nozzle plate comprising a first area, a second area, and a third area sequentially arranged in a direction away from the nozzle part with respect to the nozzle part;
an organic layer on the lower surface of the nozzle plate in the second area and the third area, and spaced apart from the first area in a plan view;
an inorganic layer on a lower surface of the organic layer in the third area and spaced apart from the first area and the second area in the plan view;
a first oxide layer on the lower surface of the nozzle plate in the first to third areas and covering the nozzle plate, the organic layer, and the inorganic layer;
a second oxide layer on a lower surface of the first oxide layer in the first to third areas; and
a liquid-repellent layer on a lower surface of the second oxide layer in the first to third areas.
